(19) United States
(12) Patent Application Publication
(10) Pub. No.: US 2013/0269992 A1
(43) Pub. Date: Oct. 17, 2013

(54) INSULATING STRUCTURE AND PRODUCTION METHOD OF SAME

(71) Applicants: Ichiro Doi, Tokyo (JP); Shozo Takada, Tokyo (JP); Reiko Mishima, Tokyo (JP); Hideo Saito, Tokyo (JP)

(72) Inventors: Ichiro Doi, Tokyo (JP); Shozo Takada, Tokyo (JP); Reiko Mishima, Tokyo (JP); Hideo Saito, Tokyo (JP)

(73) Assignee: ASAHI KASEI E-MATERIALS CORPORATION, Tokyo (JP)

(21) Appl. No.: 13/997,541

(22) PCT Filed: Dec. 22, 2011
(86) PCT No.: PCT/JP2011/079920

§ 371 Date: Jun. 24, 2013

(30) Foreign Application Priority Data
Dec. 24, 2010 (JP) 2010-287928

(51) Int. Cl. H05K 1/02; H01B 3/00

(52) U.S. Cl. CPC H05K 1/0296; H01B 3/008
USPC 174/258; 174/250; 427/58

(57) ABSTRACT

An insulating structure is formed that favorably maintains gap-fill capability of a narrow width pattern in a memory cell while also preventing the formation of cracks in an insulator in a peripheral circuit, and has the memory cell and peripheral circuit within the same layer. The present invention provides an insulating structure comprising a substrate and a circuit pattern formed on the substrate, wherein the circuit pattern has a narrow width region having a narrow width pattern of a width of 30 nm or less and a wide width region having a wide width pattern of a width of greater than 100 nm in the same layer, and the same insulating composition is formed within the narrow width pattern and within the wide width pattern.

### TECHNICAL FIELD

The present invention relates to an insulating structure used in a semiconductor device and the like and to a production method thereof. More particularly, the present invention relates to an insulating structure, in which a narrow width region having a pattern of a width of 30 nm or less and a wide width region having a pattern of a width of greater than 100 nm are present in the same layer, and a production method thereof.

### BACKGROUND ART

Semiconductor devices have continued to realize higher levels of integration each year due to the rapid advancement of microprocessing technology primarily in the area of lithography. In particular, NAND flash memory devices, which are a typical example of a semiconductor device for non-volatile memory, have achieved reductions in memory cell area by overcoming various technical problems.

In recent years however, the higher levels of integration of NAND flash memory devices that are dependent only on microprocessing technology have been indicated to have numerous technical problems. The majority of these are attributable to stagnation in efforts to further reduce size stemming from the limitations of lithography technology. Therefore, a method has been proposed for achieving higher integration through stacking of memory cells instead of solely relying on size reductions achieved using lithography technology (see, for example, Patent Document 1).

According to this method, memory devices can realize higher levels of integration in theory even if limitations on lithography technology are encountered.

### PRIOR ART DOCUMENTS

### Patent Documents

Patent Document 1: Japanese Unexamined Patent Publication No. 2009-238874

### Non-Patent Documents

Non-Patent Document 1: The International Technology Roadmap for Semiconductors, 2009 Edition, Front End Processes, p. 10

### DISCLOSURE OF THE INVENTION

### Problems to be Solved by the Invention

However, the aforementioned technology has several problems.

The first problem is that, in order to stack memory cells, the length in the longitudinal direction of insulating structures used to separate a memory cell from a memory cell adjacent thereto becomes long and the aspect ratio of processing dimensions becomes higher. A high aspect ratio processing is generally difficult for overall semiconductor process technology, particularly for lithography, etching, and the gap-fill of narrow patterns formed by these technologies. With respect to the gap-fill of narrow width patterns in particular, it is difficult to form insulators by conventionally known chemical vapor deposition (CVD), and although Patent Document 1 discloses a method for forming an insulating structure in a memory cell layered structure having a minimum processing dimension of 30 nm by lithography technology using a spin-on-glass (SOG) method, an insulating structure and method for forming that structure are not disclosed in the case the minimum processing dimension becomes even smaller.

The second problem is the occurrence of large differences in processing dimensions between memory cells and peripheral circuits. Although this has also been previously indicated with respect to NAND flash memory devices that do not employ a stacked memory cell structure (see Non-Patent Document 1), this problem is expected to become more dominant as a result of stacking memory cells. Namely, although memory cells have the problem of insulating structures requiring processing at a high aspect ratio as previously described, peripheral circuits only contain patterns having large dimensions in comparison with memory cells. As a result, in comparison with the insulators that form insulating structures in memory cells, the insulators of peripheral circuits have patterns that have the same dimensions in the longitudinal direction but are much longer in the lateral direction. Although such structures can be easily formed by CVD, insulators obtained by SOG are susceptible to the formation of cracks and are difficult to form. Patent Document 1 does not contain a description of the structural details of the insulating structure used in peripheral circuits nor does it describe a method for forming that insulating structure.

In summary of the two problems described above, although SOG is advantageous for forming the insulating structures of memory cells, their formation is difficult by CVD, and since the opposite is true in the case of their peripheral circuits, there is no method that is suitable for forming both of these in the same layer. Namely, there has been the problem of being unable to prevent the formation of cracks in insulators of peripheral circuits while maintaining favorable gap-fill of narrow width patterns in memory cells, and as a result thereof, insulating structures having memory cells and peripheral circuits in the same layer have been unable to be formed.

The present invention attempts to solve the aforementioned problems attributable to dimensional differences between memory cells and peripheral circuits when reducing the size of semiconductor memory, and thus realize higher levels of semiconductor memory integration, by providing an insulating structure in which a narrow width region and wide width region are present in the same layer, and a production method thereof.

### Means for Solving the Problems

Namely, the present invention is as described below.

[1] An insulating structure comprising a substrate and a circuit pattern formed on the substrate, wherein the circuit pattern has a narrow width region having a narrow width pattern of a width of 30 nm or less and a wide width region having a wide width pattern of a width of greater than 100 nm in the same layer, and

the same insulating composition is formed within the narrow width pattern and within the wide width pattern.

[2] The insulating structure described in [1] above, wherein the film thickness of the insulating composition present within the wide with pattern is 1.5 μm to 4.0 μm.

[3] The insulating structure described in [1] above, wherein the film thickness of the insulating composition present within the wide width pattern is 0.8 μm to 1.5 μm.

[4] The insulating structure described in any of [1] to [3] above, wherein the insulating composition present within the wide width pattern does not have cracks.

[5] The insulating structure described in any of [1] to [4] above, wherein the insulating composition present within the narrow width pattern does not have voids.

[6] The insulating structure described in any of [1] to [5] above, wherein the insulating composition present within the narrow width pattern has resistance to hydrofluoric acid.

[7] The insulating structure described in any of [1] to [6] above, wherein the depth of the narrow width pattern is 0.4 μm or more.

[8] The insulating structure described in [7] above, wherein the depth of the narrow width pattern is 0.5 μm to 3 μm.

[9] The insulating structure described in [8] above, wherein the depth of the narrow width pattern is 1 μm to 2 μm.

[10] The insulating structure described in any of [1] to [9] above, wherein the length of the narrow width pattern is 50 nm to 10 μm.

[11] The insulating structure described in any of [1] to [10] above, wherein the narrow width pattern is a pattern of a width of 10 nm to 30 nm.

[12] The insulating structure described in any of [1] to [11] above, wherein the wide width pattern is a pattern of a width of greater than 100 nm to 100 μm.

[13] The insulating structure described in any of [1] to [12] above, wherein the substrate is composed of a semiconductor or insulator.

[14] The insulating structure described in any of [1] to [13] above, wherein the insulating composition has a nanostructure of a particle diameter of 3 nm to 30 nm.

[15] An insulating structure comprising a substrate and a circuit pattern formed on the substrate, wherein

the circuit pattern has a narrow width region having a pattern of a width of 30 nm or less and a wide width region having a pattern of a width of greater than 100 nm within the same layer,

the same insulating composition is formed within the pattern having a width of 30 nm or less in the narrow width region and within the pattern of a width of greater than 100 nm in the wide width region, and

the insulating composition has a nanostructure of a particle diameter of 3 nm to 30 nm.

[16] The insulating structure described in [14] or [15] above, wherein the ratio of the portion having the nanostructure in the insulating composition is 1% by weight to 60% by weight.

[17] The insulating structure described in any of [14] to [16] above, wherein the insulating composition contains 50% by weight to 100% by weight of a condensation reaction product of a polysiloxane compound and a silica particles having an average primary particle diameter of 3 nm to 30 nm, and

the ratio of a hydrolytic condensation structure of at least one type of tetraalkoxysilane and at least one type of alkyl trialkoxysilane in the entire condensation reaction product is 40% by weight to 99% by weight.

[18] A production method of the insulating structure described in any of [1] to [17] above, comprising:

a step for preliminarily forming patterns corresponding to the narrow width region and the wide width region on a substrate,

a step for coating a coating composition for forming the insulating composition on the patterns, and

a step for converting the coated coating composition to the insulating composition by heating.

[19] The insulating structure production method described in [18] above, wherein the coating composition is a condensation reaction product solution comprising:

(I) a condensation reaction product obtained by a condensation reaction of a condensation component containing at least (i) 40% by weight to 99% by weight as the condensed amount of a polysiloxane compound derived from a silane compound represented by the following general formula (1):

R¹ₙSiX¹₄₋ₙ (1)

(wherein, n represents an integer of 0 to 3, R¹ represents a hydrocarbon group having 1 to 10 carbon atoms, and X¹ represents a halogen atom, alkoxy group having 1 to 6 carbon atoms, or an acetoxy group), and (ii) 1% by weight to 60% by weight of silica particles, and

(II) a solvent, and

the silane compound represented by the general formula (1) consists of two or more types of silane compounds comprising at least a tetrafunctional silane compound in which n in general formula (1) is 0 and a trifunctional silane compound in which n in general formula (1) is 1.

### Effects of the Invention

According to the present invention, problems in the manner of voids that easily form in a narrow width region of a semiconductor device and cracks that easily form in a wide width region can be prevented simultaneously, thereby making it possible to increase the level of integration of a semiconductor device (such as semiconductor memory) in which both such regions are present in the same layer.

### BRIEF DESCRIPTION OF THE DRAWINGS

FIG. 1 is a schematic cross-sectional view of an insulating structure according to a first aspect of the present invention.

FIG. 2 is a schematic cross-sectional view of a test substrate used in examples.

### BEST MODE FOR CARRYING OUT THE INVENTION

The following provides a detailed explanation of embodiments of the present invention.

<Insulating Structure>

One aspect of the present invention provides an insulating structure comprising a substrate and a circuit pattern formed on the substrate, wherein the circuit pattern has a narrow width region having a narrow width pattern of a width of 30 nm or less and a wide width region having a wide width pattern of a width of greater than 100 nm in the same layer, and the same insulating composition is formed within the narrow width pattern and within the wide width pattern.

Another aspect of the present invention provides an insulating structure comprising a substrate and a circuit pattern formed on the substrate, wherein the circuit pattern has a narrow width region in which is formed a pattern of a width of 30 nm or less and a wide width region in which is formed a pattern of a width of greater than 100 nm within the same layer, the same insulating composition is formed within the pattern having a width of 30 nm or less in the narrow width region and within the pattern of a width of greater than 100 nm in the wide width region, and the insulating composition has a nanostructure of a particle diameter of 3 nm to 30 nm.

The narrow width region in which is formed a pattern of a width of 30 nm or less corresponds to a memory cell, while the wide width region in which is formed a pattern of a width of greater than 100 nm corresponds to a peripheral circuit. In the present invention, a memory cell and peripheral circuit are formed within the same layer despite having a considerable difference in processing dimensions. In the present disclosure, the insulating structure having a narrow width region and wide width region within the same layer refers to that which is generally recognized by a person with ordinary skill in the art, and more specifically, refers to both regions being formed in the same step. Although a narrow width region and wide width region present within the same layer may be within the same plane, this is not always the case. An example of a case in which a narrow width region and wide width region within the same layer are not within the same plane is that in which the bottom surface of the wide width region is in a lower plane than the bottom surface of the narrow width region. The same insulating composition is filled into both the wide width pattern and narrow width pattern (also referred to as trenches). This type of insulating structure is advantageous in that it can be fabricated with fewer processes. In addition, the memory cell and peripheral circuit being formed within the same layer makes it possible to increase the level of integration of the memory cell, and enables a three-dimensional arrangement in particular. The insulating structure of the present invention can be applied over a wide range to various wiring structures and various semiconductor devices having these wiring structures.

The insulating composition used in the aforementioned insulating structure is a composition that has electrical insulating properties. Examples of insulating compositions that can be used include polysiloxane, methyl silsesquioxane, hydrogen silsesquioxane, silicon carbide and silicon nitride.

In some aspects, the insulating composition present in the wide width pattern does not have cracks. This is advantageous in terms of being able to form an insulator having a reduced number of defects in the peripheral circuit of a memory cell. In the present disclosure, the insulating composition present in the wide width pattern not having cracks means that there are no cracks of a length of 100 nm or more observed when observing an exposed surface of the wide width pattern with a scanning electron microscope (SEM).

In some aspects, the insulating composition present in the narrow width pattern does not have voids. This is advantageous in terms of being able to form an insulator having a reduced number of defects in a memory cell. In the present disclosure, the insulating composition present in the narrow width pattern not having voids means that there are no voids of a size of 3 nm or more observed when observing a cross-section of the narrow width pattern in the direction at a right angle to the lengthwise direction thereof with an SEM. Furthermore, void size refers to the maximum diameter of a void as measured from an SEM micrograph. For example, in the case a void has an elliptical shape, void size refers to the maximum diameter of that ellipse. More specifically, voids are confirmed according to the method described below. Namely, a narrow width pattern in the form of a trench is cut in a direction at a right angle to the lengthwise direction thereof, and the presence or absence of voids is judged by observing that cross-section with an SEM (SEM). In the case a void having a size of 3 nm or more is observed, the narrow width pattern is judged to contain voids. The SEM used is required to have a resolution less than the size of 3 nm of voids to be detected. An example of a method used to judge the presence or absence of voids with greater sensitivity consists of treating the aforementioned trench cross-section with a chemical capable of etching the inside thereof followed by observing with an SEM. For example, in the case an insulating composition containing silicon oxide is formed in a trench, a method can be used in which the trench cross-section is treated with a suitable concentration of hydrofluoric acid followed by observing with an SEM.

In some aspects, the insulating composition contains a nanostructure having a particle diameter of 3 nm to 30 nm. In some aspects, the insulating composition preferably contains a nanostructure having a particle diameter of 5 nm or more and more preferably 10 nm or more, and preferably contains a nanostructure having a particle diameter of 25 nm or less and more preferably 20 nm or less.

Although methods are generally known for detecting the presence of structures on the nanometer order that use a transmission electron microscope or small angle X-ray scattering, having a nanostructure of a particle diameter of 3 nm to 30 nm as referred to in the present disclosure means having a particle shape having a particle diameter (and specifically, a major axis or diameter) of 3 nm to 30 nm when a thin section having a thickness of 100 nm or less has been prepared from a cross-section of the insulating structure and that thin section is observed with a transmission electron microscope. The formation of cracks in the wide width region can be prevented by making the particle diameter of the nanostructure to be 3 nm or more. In addition, the formation of voids in the narrow width region can be prevented by making the particle diameter of the nanostructure to be 30 nm or less. This nanostructure can be formed from a portion derived from silica particles in a condensation reaction obtained by at least condensing, for example, a polysiloxane compound (such as a polysiloxane compound derived from a silane compound represented by general formula (1) to be subsequently described) and silica particles.

Although the size of the nanostructure is typically not a single value but rather has a definite width, the particle diameter of the nanostructure of the present disclosure is not required to be a single value, but rather may have a certain range provided that range is a particle diameter of 3 nm to 30 nm. In some aspects, there is the possibility of the insulating composition further having a particle shape other than a nanostructure having a particle diameter of 3 nm to 30 nm. On the other hand, in some aspects, the shape of substantially all of the particles of the insulating composition preferably has a particle diameter of 3 nm to 30 nm from the viewpoint of allowing the obtaining of favorable effects attributable to the nanostructure.

The ratio of the nanostructure in the insulating composition is preferably 1% by weight to 60% by weight. Adequate crack prevention performance can be demonstrated in the wide width region by a nanostructure that is present at a ratio within this range. The aforementioned ratio is more preferably 10% by weight to 50% by weight and even more preferably 15% by weight to 45% by weight. Furthermore, for the sake of convenience, the aforementioned ratio is confirmed by slicing the insulating structure into thin sections, observing the insulating composition, and calculating the area ratio between the nanostructure portion and other portions by carrying out image processing on the observed images. Alternatively, in an example of the case of using a value estimated on the basis of charged amounts, such as in the case of using a condensation reaction product obtained from a condensed portion containing a polysiloxane compound (such as a polysiloxane compound derived from a silane compound represented by general formula (1) to be subsequently described) and silica particles, the ratio of the amount of silica particles to the total amount of the condensed amount of the polysiloxane compound (and other condensation reaction components arbitrarily contained in the condensed portion) and the silica particles can also be used for the aforementioned ratio for the sake of convenience. Here, the condensed amount refers to the amount obtained by replacing one condensation reactive group present in the components with ½ of an oxygen atom. More specifically, a condensation reactive group refers to a group that contributes to the formation of a siloxane bond as a result of condensation (such as a halogen atom, alkoxy group or acetoxy group bound to a silicon atom). Furthermore, at least a portion (and normally a majority) of the aforementioned condensation reactive groups become silanol groups due to hydrolysis during the actual reaction, and these silanol groups are subjected to the condensation reaction.

The chemical composition of this insulating composition is such that the insulating composition can contain a condensation reaction product of a polysiloxane compound and silica particles having an average primary particle diameter of 3 nm to 30 nm at preferably 50% by weight to 100% by weight and more preferably 80% by weight to 100% by weight. In addition, the ratio of a hydrolytic condensation structure of at least one type of tetraalkoxysilane and at least one type of alkyl trialkoxysilane in the entire condensation reaction product is preferably 40% by weight to 99% by weight and more preferably 50% by weight to 90% by weight. In a more preferable aspect, the ratios of the aforementioned condensation reaction product and the aforementioned hydrolytic condensation structure are both made to be within the aforementioned ranges. Although the content of the condensation reaction product of the polysiloxane compound and the silica particles in the insulating composition is preferably 100% by weight or close thereto, void preventive effects in the narrow width region and crack preventive effects in the wide width region can be favorably demonstrated if the condensation reaction product is contained at a minimum of 50% by weight. Forming the aforementioned polysiloxane compound by hydrolytic condensation of at least one type of each of a tetraalkoxysilane and alkyl trialkoxysilane improves crack prevention performance to a greater degree than in the case of using each alone. In the case the ratio of the hydrolytic condensation structure in the entire condensation reaction product is 40% by weight or more, inhibition of void formation in the narrow width region is particularly favorable, and in the case the ratio is 99% or less, crack prevention performance is particularly favorable. Examples of tetraalkoxysilanes include tetramethoxysilane and tetraethoxysilane. In addition, examples of alkyl trialkoxysilanes include methyl trimethoxysilane, methyl triethoxysilane, ethyl trimethoxysilane and ethyl triethoxysilane. Furthermore, although the ratio of the hydrolytic condensation structure of the tetraalkoxysilane and the alkyl trialkoxysilane in the entire condensation reaction product can be confirmed by ²⁹Si NMR analysis, it can also be estimated from the charged amounts by suitably using the ratio of the total of the condensed amount of the tetraalkoxysilane and the condensed amount of the alkyl trialkoxysilane to the total of the condensed amount of condensation reactive components and silica particles for the aforementioned ratio.

The aforementioned silica particles are for forming the nanostructure possessed by the insulating structure of the present invention, and the ratio of a portion derived from the silica particles to the entire condensation product of the silica particles and polysiloxane compound is preferably 1% by weight to 60% by weight and more preferably 10% by weight to 50% by weight.

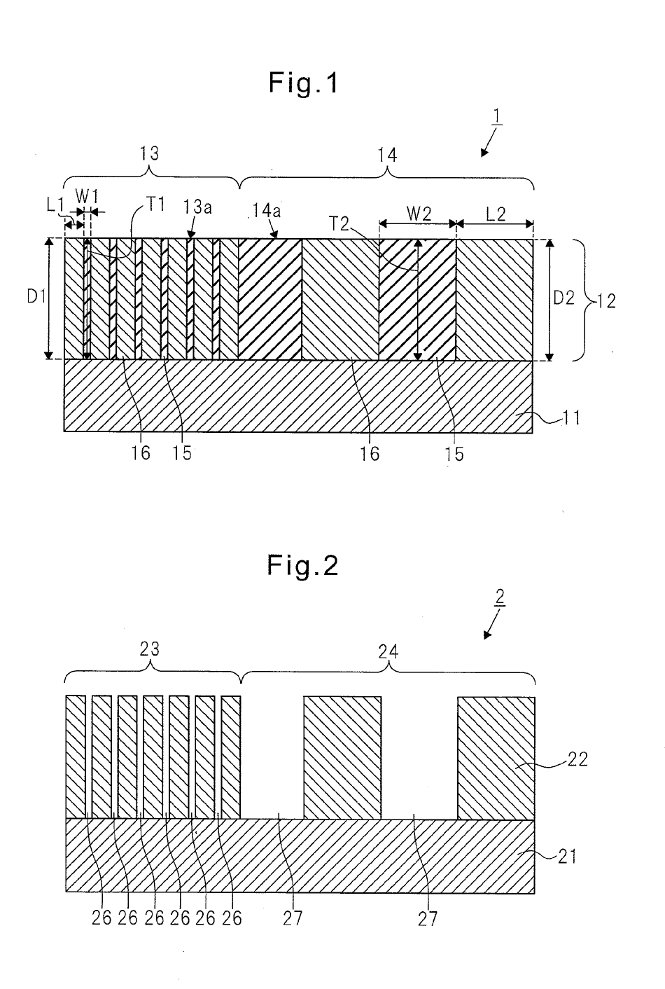

The following provides a more detailed explanation of the insulating structure of the present invention with reference to FIG. 1. Furthermore, the proportions of the structures shown in FIGS. 1 and 2 are not necessarily to scale. In an insulating structure 1 shown in FIG. 1, a circuit pattern 12 composed of a narrow width region 13 and a wide width region 14 is formed on a substrate 11. In the present invention, the narrow width region 13 and the wide width region 14 are present within the same layer. In other words, although the narrow width region 13 is first formed by forming a desired pattern in a photoresist by lithography followed by removing the unnecessary portion by etching and forming the required pattern on the substrate by transferring the pattern of the photoresist, a required pattern is also simultaneously formed in the wide width region 14 at this time. After going through this step, the insulating structure of the present invention is completed by filling the pattern of the narrow width region and the pattern of the wide width region with the same insulating composition 15.

The substrate 11 can be formed with an arbitrary material widely known in the art. The substrate 11 is preferably formed with a conductor or semiconductor, and is more preferably formed with a semiconductor. In addition, a circuit member 16 can be formed from an arbitrary material widely known in the art corresponding to the function and structure of the semiconductor device to which the insulating structure is applied. For example, in the case the insulating structure is used to isolate one transistor from another transistor, a semiconductor is preferably used for the circuit member 16. The circuit member 16 is not necessarily required to be composed of a single material, but rather may also be a structure composed of a plurality of materials. In addition, the circuit member 16 and the substrate 11 may be composed of the same material.

A composition having electrical insulating properties is used for the insulating composition used in the insulating structure of the present invention. In consideration of the object of the present invention, although having electrical insulating properties refers to having adequately high breakdown voltage or adequately low leakage current between each element of a semiconductor device, actually fabricating a semiconductor device and measuring breakdown voltage and leakage current require considerable time. Thus, in the present disclosure, having electrical insulating properties means that, when the insulating composition used in the present invention is formed into a thin film having a film thickness of about 100 nm to 500 nm and a voltage is applied thereto, the electric field strength at which the insulation breaks down is 3 MV/cm or more.

The narrow width region 13 refers to a region having a narrow width pattern 13a of a width W1 of 30 nm or less. The width W1 of the narrow width pattern 13a is preferably 25 nm or less, more preferably 20 nm or less and even more preferably 15 nm or less from the viewpoint of reducing the size of the semiconductor device, and is preferably 10 nm or more, more preferably 12 nm or more and even more preferably 14 nm or more from the viewpoint of the ease of lithography, etching and other size reduction processes.

In the present disclosure, the width of each pattern refers to an opening width.

The width W1 is measured by observing with an SEM in the case the opening is exposed on the surface of the insulating structure, or by observing a cross-section at a right angle to the opening in the case it is not exposed.

The wide width region 14 refers to a region having a wide width pattern 14a of a width W2 of greater than 100 nm. The width W2 of the wide width pattern 14 is preferably 200 nm or more, more preferably 500 nm or more and even more preferably 1 μm or more from the viewpoint of reliability of the semiconductor device in which the semiconductor structure is applied, and is preferably 100 μm or less, more preferably 50 μm or less, even more preferably 5 μm or less and particularly preferably 5 μm or less from the viewpoint of reducing the size of the semiconductor device. The width W2 is measured using the same method as that used to measure the width W1.

The circuit pattern in the insulating structure of the present invention at least has a narrow width region and a wide width region, and may also have a region other than the narrow width region and wide width region. In addition, the narrow width region and the wide width region can be arranged in various ways, and can be suitably designed by a person with ordinary skill in the art. Although FIG. 1 shows an example in which the narrow width region 13 has a plurality of narrow width patterns of a width prescribed by the present invention and the wide width region 14 has a plurality of wide width patterns of a width prescribed by the present invention, the present invention is not limited thereto. Each narrow width region 13 and wide width region 14 includes a region having at least one pattern of a width prescribed by the present invention. An example of a preferable arrangement of both regions is that in which a wide width region is arranged around a narrow width region having a large, cyclical number of narrow width patterns as observed in a semiconductor memory device.

The widths of the narrow width pattern and wide width pattern may each be constant regardless of the location of the pattern in the direction of depth, or may vary corresponding to the location in the direction of depth. An example of the latter is a so-called forward tapered shape in which the width of the bottom of a pattern is narrower than the width of the opening of a pattern. From the viewpoint of reducing the size of a semiconductor device, the widths of the bottom of a pattern and the opening of a pattern are ideally equal, or are preferably as close to being equal as possible.

A depth D1 of the narrow width pattern 13a of the narrow width region 13 is preferably 0.4 μm or more. The depth D1 is more preferably 0.5 μm or more and even more preferably 1 μm or more from the viewpoint of employing a three-dimensional configuration for a semiconductor device, and is preferably 4 μm or less, more preferably 3 μm or less and even more preferably 2 μm or less from the viewpoint of ease of lithography or etching processing. The depth D1 refers to the depth from the aperture to the deepest portion of a pattern. The depth D1 is measured by observing a cross-section of the pattern with an SEM.

A film thickness T2 of the insulating composition 15 present in the wide width pattern 14a of the wide width region 14 is preferably 0.8 μm to 4 μm and more preferably 0.8 μm to 1.5 μm. In another preferable aspect, the film thickness T2 is preferably 1.5 μm to 4 μm. The film thickness T2 is measured by observing a cross-section in the same manner as the aforementioned depth D1.

In some aspects, the top surface of the insulating composition 15 and the top surface of the circuit member 16 can be roughly in the same plane in each of the narrow width region and wide width region or in both the narrow width region and wide width region. In a typical aspect, a film thickness T1 of the insulating composition present in a narrow width pattern is equal to the depth D1 of the narrow width pattern. In a typical aspect, the film thickness T2 of the insulating composition in a wide width pattern is equal to a depth D2 of the wide width pattern. In a more typical aspect, the values of T1, D1, T2 and D2 are equal.

A width L1 of the circuit member 16 of the narrow width region 13 is preferably 10 nm or more. The width L1 is preferably 10 nm or more, more preferably 20 nm or more and even more preferably 30 nm or more from the viewpoint of ease of lithography and etching, and is preferably 100 nm or less and more preferably 50 nm or less from the viewpoint of reducing the size of a semiconductor device. The width L1 is measured using the same method as that used to measure width W1.

A width L2 of the circuit member 16 of the wide area region 14 is preferably 100 nm to 100 μm. The width L2 is preferably 100 nm or more, more preferably 500 nm or more and even more preferably 1 μm or more from the viewpoint of ease of lithography and etching, and is preferably 100 μm or less, more preferably 10 μm or less and even more preferably 5 μm or less from the viewpoint of reducing the size of a semiconductor device. The width L2 is measured using the same method as that used to measure the width L1.

Although the lengths of the narrow width pattern and wide width pattern, namely the dimensions thereof in the direction of length, can be suitably designed by a person with ordinary skill in the art, they are preferably 50 nm to 10 μm each. The lengths are preferably 50 nm or more, more preferably 500 nm or more and even more preferably 1 μm or more from the viewpoint of ease of lithography and etching, and are preferably 10 μm or less, more preferably 5 μm or less and even more preferably 2 μm or less from the viewpoint of reducing the size of a semiconductor device. The aforementioned lengths are measured by SEM observation in the same manner as the width L1 and the width L2.

The insulating composition present in the narrow width pattern 13a of the narrow width region 13 preferably has resistance to hydrofluoric acid. In the present disclosure, the insulating composition present in the narrow width pattern having resistance to hydrofluoric acid means that after having cut a narrow width pattern at a right angle to the lengthwise direction thereof to expose a cross-section and then treating that cross-section with hydrofluoric acid under suitable conditions, there are no voids present as previously defined when observed with an SEM. The conditions of hydrofluoric acid treatment can be suitably selected according to the type of insulating composition. Typically, conditions under which the insulating composition is etched by 10 nm to 100 nm are employed to facilitate confirmation of the presence or absence of voids by SEM observation.

<Insulating Structure Production Method>

In another aspect of the present invention, a method is provided for producing the aforementioned insulating structure of the present invention, comprising a step for preliminarily forming patterns corresponding to the narrow width region and the wide width region on a substrate, a step for coating a coating composition for forming the insulating composition on the patterns, and a step for converting the coated coating composition to an insulating composition by heating. For example, a method for producing the insulating structure of the present invention as shown in FIG. 1 preferably consists of preliminarily forming patterns corresponding to the narrow width region 13 and the wide width region 14 in the same layer on the substrate 11 followed by coating a coating composition for forming the insulating composition 15, and then heating the coating composition to form the insulating composition 15. A known method is suitably selected and used from among lithography and etching as previously described to form the narrow width region 13 and the wide width region 14. Although there are no particular limitations thereon, the method used to coat the coating composition is preferably a method that easily allows the obtaining of a desired film thickness in the manner of spin coating. Although there are no particular limitations on the heating method, a solvent is preferably first evaporated at a temperature of 80° C. to 150° C. followed by baking at a temperature of 200° C. to 800° C. in order to stably form the insulating structure of the present invention. The baking temperature is suitably set in consideration of the chemical composition of the insulating composition as well as those elements insulated by the insulating structure, such as the heat resistance of memory cells in a semiconductor memory.

[Coating Composition]

The coating composition used in the insulating structure production method according to one aspect of the present invention preferably uses a condensation reaction product solution comprising:

(I) a condensation reaction product obtained by a condensation reaction of a condensation component containing at least (i) 40% by weight to 99% by weight as the condensed amount of a polysiloxane compound derived from a silane compound represented by the following general formula (1):

R¹ₙSiX¹₄₋ₙ (1)

(wherein, n represents an integer of 0 to 3, R¹ represents a hydrocarbon group having 1 to 10 carbon atoms, and X¹ represents a halogen atom, alkoxy group having 1 to 6 carbon atoms, or an acetoxy group), and (ii) 1% by weight to 60% by weight of silica particles, and

(II) a solvent, and

the silane compound represented by the general formula (1) consists of two or more types of silane compounds comprising at least a tetrafunctional silane compound in which n in general formula (1) is 0 and a trifunctional silane compound in which n in general formula (1) is 1. Namely, the aforementioned condensation reaction product is obtained by a condensation reaction of a condensation component containing in a prescribed composition a polysiloxane compound, derived from two or more types of silane compounds represented by the aforementioned general formula (1) that are least comprised of a tetrafunctional silane compound and a trifunctional silane compound, and silica particles. In the case of using a solution of this condensation reaction product, an insulating structure having a memory cell and peripheral circuit in the same layer can be formed while favorably preventing the formation of cracks in an insulator.

(Polysiloxane Compound Derived from Silane Compound Represented by General Formula (1))

The polysiloxane compound used to form a coating composition is preferably derived from a silane compound represented by the aforementioned general formula (1). More specifically, the polysiloxane compound is a polycondensate of a silane compound represented by the aforementioned general formula (1). Moreover, the silane compound represented by general formula (1) used in the present invention consists of two or more types of silane compounds at least comprising a tetrafunctional silane compound in which n in general formula (1) is 0 and a trifunctional silane compound in which n in general formula (1) is 1.

Specific examples of R¹ in the aforementioned general formula (1) include acyclic and cyclic aliphatic hydrocarbon groups such as a methyl, ethyl, n-propyl, isopropyl, n-butyl, sec-butyl, t-butyl, n-pentyl, iso-pentyl, neopentyl, cyclopentyl, n-hexyl, iso-hexyl, cyclohexyl, n-heptyl, iso-heptyl, n-octyl, iso-octyl, t-octyl, n-nonyl, iso-nonyl, n-decyl or iso-decyl group; acyclic and cyclic alkenyl groups such as a vinyl, propenyl, butenyl, pentenyl, hexenyl, cyclohexenyl, cyclohexenylethyl, norbornenylethyl, heptenyl, octenyl, nonenyl, decenyl or styrenyl group; aralkyl groups such as a benzyl, phenethyl, 2-methylbenzyl, 3-methylbenzyl or 4-methylbenzyl group; aralkenyl groups such as a PhCH═CH— group; and, aryl groups such as a phenyl group, tolyl group or xylyl group. Moreover, a specific example of R¹ is also a hydrogen atom. Among these, from the viewpoints of little weight loss during conversion to silicon oxide when baking and being able to impart a condensation reaction product having a low shrinkage factor, R¹ is preferably a hydrogen atom, methyl group or ethyl group, and more preferably a methyl group.

Specific examples of X¹ in the aforementioned general formula (1) include halogen atoms such as a chlorine, bromine or iodine atom; alkoxy groups such as a methoxy group, ethoxy group, n-propyloxy group, iso-propyloxy group, n-butyloxy group, t-butyloxy group, n-hexyloxy group or cyclohexyloxy group; and an acetoxy group. Among these, halogen atoms such as an iodine atom, alkoxy groups such as a methoxy group or ethoxy group, and an acetoxy group are preferable due to the high reactivity of the condensation reaction.

As a result of the polysiloxane compound derived from a silane compound represented by general formula (1) containing a component derived from a tetrafunctional silane compound in which n is general formula (1) is 0, film formation of the insulating composition and adhesion to the substrate are favorable. As a result of the polysiloxane compound containing a component derived from a trifunctional silane compound in which n in general formula (1) is 1, cracking resistance and hydrofluoric acid (HF) resistance of the insulating composition are favorable and gap-fill capability is also favorable. The total amount of the component derived from a tetrafunctional silane compound and the component derived from a trifunctional silane compound in the entire polysiloxane compound derived from a silane compound represented by general formula (1) based on the number of moles of each silane compound is preferably 90 mol % to 100 mol % and more preferably 95 mol % to 100 mol %. As a result of making the total amount of the component derived from a tetrafunctional silane compound and the component derived from a trifunctional silane compound to be within the range of this ratio, film formation, adhesion to the substrate, cracking resistance and HF resistance are further improved, and film formation on various substrates is particularly favorable. In the present invention, in the case of using a polysiloxane compound derived from two or more types of silane compounds having the specific composition described above, a condensation reaction product solution is obtained that is able to form an insulating composition having favorable film formation, substrate adhesion, cracking resistance, HF resistance and gap-fill capability. The following provides an explanation of more preferable aspects of the tetrafunctional silane compound and trifunctional silane compound.

The ratio of a component derived from a tetrafunctional silane compound represented by the following general formula (2):

SiX²₄ (2)

(wherein, X² represents a halogen atom, alkoxy group having 1 to 6 carbon atoms or an acetoxy group) in a polysiloxane compound derived from a silane compound represented by general formula (1) that can be used in the present invention is preferably 5 mol % to 40 mol %. Furthermore, the structure of X² in the aforementioned general formula (2) corresponds to the structure of X¹ in the aforementioned general formula (1), and the structure of general formula (2) represents a portion of the structure of general formula (1). In the case the ratio of the component derived from a tetrafunctional silane compound represented by general formula (2) in the polysiloxane compound derived from a silane compound represented by general formula (1) is 5 mol % or more, film formation and substrate adhesion are favorable, thereby making this preferable, and this ratio is more preferably 10 mol % or more. On the other hand, in the case this ratio is 40 mol % or less, HF resistance is favorable, thereby making this preferable, and this ratio is more preferably 35 mol % or less and even more preferably 30 mol % or less.

Specific examples of X² in the aforementioned general formula (2) include halogen atoms such as a chlorine, bromine or iodine atom; alkoxy groups such as a methoxy group, ethoxy group, n-propyloxy group, iso-propyloxy group, n-butyloxy group, t-butyloxy group, n-hexyloxy group or cyclohexyloxy group; and an acetoxy group. Among these, halogen atoms such as an iodine atom, alkoxy groups such as a methoxy group or ethoxy group and an acetoxy group are preferable due to the high reactivity of the condensation reaction.

In particular, an aspect in which the condensation component used in the present invention contains 50% by weight to 90% by weight as the condensed amount of the polysiloxane compound represented by general formula (1) and 10% by weight to 50% by weight of silica particles, and the ratio of the component derived from a tetrafunctional silane compound represented by the aforementioned general formula (2) in the polysiloxane compound is 5 mol % to 40 mol %, is particularly preferable.

The ratio of the component derived from a trifunctional silane compound represented by the following general formula (3):

R²SiX³₃ (3)

(wherein, R² represents a hydrocarbon group having 1 to 10 carbon atoms and X³ represents a halogen atom, alkoxy group having 1 to 6 carbon atoms or an acetoxy group) in the polysiloxane compound derived from a silane compound represented by general formula (1) that can be used in the present invention is preferably 60 mol % to 95 mol %. Furthermore, the structure of X³ in the aforementioned general formula (3) corresponds to X¹ in the aforementioned general formula (1), and the structure of R² in the aforementioned general formula (3) represents a partial aspect of R¹ in the aforementioned general formula (1). Namely, the structure of general formula (3) represents a portion of the structure of general formula (1). In the case the ratio of the component derived from a trifunctional silane compound represented by general formula (3) in the polysiloxane compound is 60 mol % or more, in addition to HF resistance and cracking resistance being favorable, gap-fill capability is also favorable, thereby making this preferable, and the ratio is more preferably 65 mol % or more and even more preferably 70 mol % or more. On the other hand, in the case the ratio is 95 mol % or less, film formation and substrate adhesion are preferable, thereby making this preferable, and the ratio is more preferably 90 mol % or less.

Furthermore, the structure of the polysiloxane compound, and particularly the presence and contents of structures respectively represented by the aforementioned general formulas (1), (2) and (3), can be confirmed by ²⁹Si NMR analysis.

Specific examples of R² in the aforementioned general formula (3) include acyclic or cyclic aliphatic hydrocarbon groups such as methyl, ethyl, n-propyl, isopropyl, n-butyl, sec-butyl, t-butyl, n-pentyl, iso-pentyl, neopentyl, cyclopentyl, n-hexyl, iso-hexyl, cyclohexyl, n-heptyl, iso-heptyl, n-octyl, iso-octyl, t-octyl, n-nonyl, iso-nonyl, n-decyl or iso-decyl groups; acyclic or cyclic alkenyl groups such as vinyl, propenyl, butenyl, pentenyl, hexenyl, cyclohexenyl, cyclohexenylethyl, norbornenylethyl, heptenyl, octenyl, nonenyl, decenyl or styrenyl groups; aralkyl groups such as benzyl, phenethyl, 2-methylbenzyl, 3-methylbenzyl or 4-methylbenzyl groups; aralkenyl groups such as PhCH═CH— group; and, aryl groups such as phenyl group, tolyl group or xylyl group. Among these, from the viewpoints of little weight loss during conversion to silicon oxide when baking and being able to impart a condensation reaction product having a low shrinkage factor, R² is preferably a methyl group or ethyl group, and more preferably a methyl group.

Specific examples of X² in the aforementioned general formula (3) include halogen atoms such as a chlorine, bromine or iodine atom; alkoxy groups such as a methoxy group, ethoxy group, n-propyloxy group, iso-propyloxy group, n-butyloxy group, t-butyloxy group, n-hexyloxy group or cyclohexyloxy group; and an acetoxy group. Among these, halogen atoms such as a chlorine atom, bromine atom or iodine atom, alkoxy groups such as a methoxy group or ethoxy group, and an acetoxy group are preferable due to their high reactivity in the condensation reaction.

(Production of Polysiloxane Compound Derived from Silane Compound Represented by General Formula (1))

The aforementioned polysiloxane compound can be produced, for example, by method in which the aforementioned silane compound is subjected to polycondensation in the presence of water. At this time, polycondensation is carried out in the presence of water within a range of preferably 0.1 equivalents to 10 equivalents and more preferably 0.4 equivalents to 8 equivalents based on the number of X¹ contained in the silane compound represented by the aforementioned general formula (1) in an acidic atmosphere. In the case the amount of water present is within the aforementioned ranges, the pot life of the condensation reaction product solution is prolonged and cracking resistance of the film following film formation can be improved, thereby making this preferable.

In the case the silane compound used to produce the aforementioned polysiloxane compound contains a halogen atom or acetoxy group for X¹ in the aforementioned general formula (1), the reaction system demonstrates acidity as a result of adding water for the condensation reaction. Accordingly, in this case, an acid catalyst may or may not be used in addition to the silane compound. On the other hand, in the case X¹ in the aforementioned general formula (1) is an alkoxy group, the addition of an acid catalyst is preferable.

Examples of acid catalysts include inorganic acids and organic acids. Examples of the aforementioned inorganic acids include hydrochloric acid, nitric acid, sulfuric acid, hydrofluoric acid, phosphoric acid and boric acid. Examples of the aforementioned organic acids include acetic acid, propionic acid, butanoic acid, heptanoic acid, hexanoic acid, heptanoic acid, octanoic acid, nonanoic acid, decanoic acid, oxalic acid, maleic acid, methylmalonic acid, benzoic acid, p-aminobenzoic acid, p-toluenesulfonic acid, benzenesulfonic acid, trifluoroacetic acid, formic acid, malonic acid, sulfonic acid, phthalic acid, fumaric acid, citric acid, tartaric acid, citraconic acid, malic acid and glutaric acid.

One type of the aforementioned inorganic acids and organic acids can be used or two or more types can be used by mixing. In addition, the amount of acid catalyst used is preferably an amount that adjusts the pH of the reaction system when producing the polysiloxane compound to 0.01 to 7.0 and preferably 5.0 to 7.0. In this case, the weight average molecular weight of the polysiloxane compound can be favorably controlled.

The polysiloxane compound can be produced in an organic solvent or in a mixed solvent of water and an organic solvent. Examples of the aforementioned organic solvent include alcohols, esters, ketones, ethers, aliphatic hydrocarbons, aromatic hydrocarbons and amide compounds.

Examples of the aforementioned alcohols include monovalent alcohols such as methyl alcohol, ethyl alcohol, propyl alcohol or butyl alcohol; polyvalent alcohols such as ethylene glycol, diethylene glycol, propylene glycol, glycerin, trimethylolpropane or hexanetriole; and monoethers of polyvalent alcohols such as ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, propylene glycol monomethyl ether, propylene glycol monoethyl ether, propylene glycol monopropyl ether or propylene glycol monobutyl ether.

Examples of the aforementioned esters include methyl acetate, ethyl acetate and butyl acetate.

Examples of the aforementioned ketones include methyl ethyl ketone and methyl isoamyl ketone.

Examples of the aforementioned ethers include, in addition to the aforementioned monoethers of polyvalent alcohols, polyvalent alcohol ethers in which all of the hydroxyl groups of the polyvalent alcohol have been alkyl etherified, such as ethylene glycol dimethyl ether, ethylene glycol diethyl ether, ethylene glycol dipropyl ether, ethylene glycol dibutyl ether, propylene glycol dimethyl ether, propylene glycol diethyl ether, propylene glycol dibutyl ether, diethylene glycol dimethyl ether, diethylene glycol methyl ethyl ether or diethylene glycol diethyl ether; tetrahydrofuran, 1,4-dioxane and anisole.

Examples of the aforementioned aliphatic hydrocarbons include hexane, heptane, octane, nonane and decane.

Examples of the aforementioned aromatic hydrocarbons include benzene, toluene and xylene.

Examples of the aforementioned amide compounds include dimethylformamide, dimethylacetoamide and N-methylpyrrolidone.

Among the aforementioned solvents, alcohol-based solvents such as methanol, ethanol, isopropanol or butanol; ketone-based solvents such as acetone, methyl ethyl ketone or methyl isobutyl ketone; ether-based solvents such as ethylene glycol monomethyl ether, diethylene glycol monobutyl ether, propylene glycol monomethyl ether or propylene glycol monoethyl ether; and amide compound-based solvents such as dimethylformamide, dimethylacetoamide or N-methylpyrrolidone are preferable in terms of being readily miscible with water and easily dispersing silica particles.

In a preferable aspect, the polysiloxane compound can be produced by hydrolytic polycondensation in an aqueous alcohol solution under weakly acidic conditions of a pH of 5 to less than 7.

These solvents may be used alone or a plurality of types of solvents may be used in combination. In addition, the reaction may also be carried out in bulk without using the aforementioned solvents.

Although there are no particular limitations on the reaction temperature when producing the polysiloxane compound, the reaction is preferably carried out within a range of −50° C. to 200° C. and more preferably within a range of 0° C. to 150° C. As a result of carrying out the reaction within the aforementioned temperature ranges, the molecular weight of the polysiloxane compound can be easily controlled.

In a preferable aspect, the content of the polysiloxane compound derived from a silane compound represented by general formula (1) in the condensation component is set so that the amount of the polysiloxane compound as the condensed amount thereof is 40% by weight to 99% by weight. The condensed amount of the polysiloxane compound as described above refers to the amount obtained by replacing a residual X¹ in the aforementioned polysiloxane compound (X¹ is as previously defined in general formula (1)) with ½ of an oxygen atom. The condensed amount is preferably 40% or more in that film formation and gap-fill capability of the coating composition are favorable. The condensed amount is more preferably 50% by weight or more and even more preferably 55% by weight or more. On the other hand, the condensed amount is preferably 99% by weight or less in that low shrinkage factor and favorable cracking resistance are obtained for the insulating composition. The condensed amount is more preferably 90% by weight or less and even more preferably 85% by weight or less.

(Silica Particles)

Examples of the silica particles used in the present invention include fumed silica and colloidal silica.

The aforementioned fumed silica can be obtained by reacting a compound containing silica atoms with oxygen and hydrogen in the vapor phase. Examples of silicon compounds serving as raw material include silicon halides (such as silicon chloride).

The aforementioned colloidal silica can be synthesized by a sol gel method consisting of hydrolyzing and condensing a raw material compound. Examples of raw material compounds of colloidal silica include alkoxysilanes (such as tetraethoxysilane) and halogenated silicon compounds (such as diphenyldichlorosilane). Among these, colloidal silica obtained from an alkoxysilane is more preferable since it contains low levels of metals, halogens and other impurities.

The average primary particle diameter of the silica particles is preferably 1 nm to 120 nm, more preferably 40 nm or less, even more preferably 20 nm or less and most preferably 15 nm or less. In the case the aforementioned average primary particle diameter is 1 nm or more, cracking resistance of the insulating composition is favorable, thereby making this preferable, while in the case the average primary particle diameter is 120 nm or less, gap-fill capability of the coating composition is favorable, thereby making this preferable.

The average secondary particle diameter of the silica particles is preferably 2 nm to 250 nm, more preferably 80 nm or less, even more preferably 40 nm or less and most preferably 30 nm or less. In the case the aforementioned average secondary particle diameter is 2 nm or more, cracking resistance of the insulating composition is favorable, thereby making this preferable, while in the case the average secondary particle diameter is 250 nm or less, gap-fill capability of the coating composition is favorable, thereby making this preferable.

In addition, silica particles having an average secondary particle diameter that is within the aforementioned ranges and is 0.1 to 3 times the minimum opening width of trenches formed in the substrate is preferable in terms of favorable trench-fill capability, and is more preferably 0.1 to 2 times the aforementioned minimum opening width.

The aforementioned average primary particle diameter is a value that is determined by calculating from specific surface area as determined with the BET method, while the aforementioned average secondary particle diameter is a value measured with a dynamic light scattering photometer.

Although the shape of the silica particles can be spherical, linear, flat, fibrous or a shape obtained by combining two or more types thereof, it is preferably spherical. Furthermore, “spherical” here refers to a roughly spherical shape, and includes the case of a perfect sphere, oblate spheroid or ovaloid and the like.

The specific surface area of the silica particles as determined by the BET method is preferably 23 m²/g to 2700 m²/g, more preferably 35 m²/g to 2700 m²/g, even more preferably 135 m²/g to 2700 m²/g, and particularly preferably 180 m²/g to 2700 m²/g from the viewpoint of favorable HF resistance.

The aforementioned specific surface area as determined by the BET method is a value measured by method in which specific surface area is calculated from the pressure of N₂ molecules and the amount of adsorbed gas.

There are no particular limitations on the silica particles provided they satisfy the aforementioned requirements, and commercially available products can also be used.

Examples of commercially available colloidal silica include members of the Evasil series (H.C. Starck GmbH), Methanol Silica Sol, IPA-ST, MEK-ST, NBA-ST, XBA-ST, DMAC-ST, ST-UP, ST-OUP, ST-20, ST-40, ST-C, ST-N, ST-O, ST-50, ST-OL (Nissan Chemical Industries, Ltd.), members of the Quartron PL series (Fuso Chemical Co., Ltd.), and members of the Oscal series (JGC C&C Ltd.); and examples of powdered silica particles include Aerosil 130, Aerosil 300, Aerosil 380, Aerosil TT600, Aerosil OX50, Aerosil H51, Aerosil H52, Aerosil H121, Aerosil H122 (Asahi Glass Co., Ltd.), E220A, E220 (Nippon Silica Industrial Co., Ltd.), Sylysia 470 (Fuji Sylysia Chemical Co., Ltd.), and SG Flake (Nippon-Sheet Glass Co., Ltd.). The silica particles can also be used dispersed in a dispersion medium. The content thereof in that case is calculated using a value obtained by multiplying the concentration of the silica particles by the net weight of the silica particles, namely the weight of the dispersion.

The content of the silica particles in the condensation component is preferably 1% by weight to 60% by weight. In the case the content is 1% by weight or more, the shrinkage of the insulating composition is low and cracking resistance is favorable, thereby making this preferable. The content is more preferably 10% by weight or more and more preferably 15% by weight or more. On the other hand, in the case the content is 60% by weight or less, film formation and gap-fill capability of the coating composition are favorable, thereby making this preferable. The content is more preferably 50% by weight or less and even more preferably 45% by weight or less.

(Silane Compound)

The condensation component used when producing a condensation reaction product able to be used in the present invention can be composed of the polysiloxane compound derived from a silane compound represented by the aforementioned general formula (1) and silica particles, and can also contain other components. A silane compound represented by the aforementioned general formula (1), for example, can be used as another component. In this case, a condensation reaction consisting of the following two stages, for example, can be employed. Namely, the polysiloxane compound and silica particles are first subjected to a condensation reaction by, for example, a method in which a solution of the polysiloxane compound is added to a dispersion obtained by dispersing the silica particles in a solvent (first stage). Next, a silane compound represented by the aforementioned general formula (1) is further reacted with the resulting reaction solution (second stage). The silane compound represented by general formula (1) used as a condensation component may consist of one type or a plurality of types. In the case of using a plurality of types of silane compounds, one type of each silane compound may be sequentially added to the reaction system or a plurality of types may be mixed and then added to the reaction system in the aforementioned second stage, for example.

In the case of using a silane compound represented by the aforementioned general formula (1) as a condensation component, the content of the silane compound in the condensation component is preferably set to be greater than 0% by weight to 40% by weight as the condensed amount of the silane compound. Here, the condensed amount of the silane compound refers to the amount obtained by replacing X¹ in general formula (1) with ½ of an oxygen atom. In the case the condensed amount exceeds 0% by weight, the pot life of the condensation reaction product solution is prolonged, thereby making this preferable. The condensed amount is more preferably 0.01% by weight or more and even more preferably 0.03% by weight or more. On the other hand, in the case the condensed amount is 40% by weight or less, cracking resistance of the insulating composition is favorable, thereby making this preferable. The condensed amount is more preferably 30% by weight or less and even more preferably 20% by weight or less.

(Properties of Condensation Reaction Product)

When a tetrafunctional siloxane component derived from silica particles and a tetrafunctional silane compound in which n=0 in a silane compound represented by the aforementioned general formula (1) (namely, that represented by the aforementioned general formula (2)) is defined as a component Q, then the amounts of components Q0 to Q4, respectively corresponding to components in which the number of siloxane bonds is 0 to 4, can be determined by solution or solid-state ²⁹Si NMR analysis. In the present invention, the ratio between the peak intensity (A) of all tetrafunctional siloxane components (namely, a component corresponding to 0 siloxane bonds (component Q0), a component corresponding to 1 siloxane bond (component Q1), a component corresponding to 2 siloxane bonds (component Q2), a component corresponding to 3 siloxane bonds (component Q3), and a component corresponding to 4 siloxane bonds (component Q4)) and the peak intensity (B) of the component corresponding to 4 siloxane bonds (namely, component Q4) preferably satisfies the relationship of (B)/(A)≧0.50. The aforementioned ratio is more preferably such that (B)/(A)≧0.6 and even more preferably such that (B)/(A)≧0.7. In the case the aforementioned ratio is within the aforementioned ranges, there are few terminal groups such as silanol groups or alkoxy groups in the condensation reaction product, thereby lowering curing shrinkage of the coating composition and improving gap-fill capability of the coating composition, and pot life of the condensation reaction product solution is prolonged, thereby making this preferable. Furthermore, the peak intensity of each component Q is calculated from peak area.

The weight average molecular weight of the condensation reaction product is preferably 1,000 to 20,000 and more preferably 1,000 to 10,000. In the case the weight average molecular weight of the condensation reaction product is 1,000 or more, film formation of the coating composition and cracking resistance of the insulating composition are favorable, while in the case the weight average molecular weight is 20,000 or less, gap-fill capability of the coating composition is favorable and the pot life of the condensation reaction product solution is prolonged, thereby making this preferable. Furthermore, the aforementioned weight average molecular weight is a value measured using gel permeation chromatography followed by calculating by converting on the basis of polymethyl methacrylate. Molecular weight can be determined by measuring a 1% by weight solution of the condensation reaction product in an acetone solvent using the HLC-8220 gel permeation chromatograph (GPC) manufactured by Tosoh Corp. and a TSKgel GMH_{HR}-M column, and weight average molecular weight (Mw) can be determined by converting on the basis of polymethyl methacrylate with a differential refractometer (RI).

(Solvent)

The condensation reaction product solution contains a solvent. Examples of solvents include at least one type of solvent selected from the group consisting of alcohol-, ketone-, ester-, ether- and hydrocarbon-based solvents, and esters, ethers and hydrocarbon-based solvents are more preferable. In addition, the boiling point of these solvents is preferably 100° C. to 200° C. The content of solvent in the condensation reaction product solution is preferably 100 parts by weight to 1900 parts by weight and more preferably 150 parts by weight to 900 parts by weight based on 100 parts by weight of the reaction product. In the case the content of the solvent is 100 parts by weight or more, the pot life of the condensation reaction product solution is prolonged, while in the case the content is 1900 parts by weight or less, gap-fill capability of the coating composition is favorable, thereby making this preferable.

Specific examples of the aforementioned alcohol-, ketone-, ester-, ether- and hydrocarbon-based solvents include alcohol-based solvents such as butanol, pentanol, hexanol, octanol, methoxyethanol, ethoxyethanol, propylene glycol monomethoxy ether and propylene glycol monoethoxy ether; ketone-based solvents such as methyl ethyl ketone, methyl isobutyl ketone, isoamyl ketone, ethyl hexyl ketone, cyclopentanone, cyclohexanone or γ-butyrolactone; ester-based solvents such as butyl acetate, pentyl acetate, hexyl acetate, propyl propionate, butyl propionate, pentyl propionate, hexyl propionate, propylene glycol monomethyl ethyl acetate or ethyl lactate; ether-based solvents such as butyl ethyl ether, butyl propyl ether, dibutyl ether, anisole, ethylene glycol dimethyl ether, ethylene glycol diethyl ether, propylene glycol dimethyl ether, propylene glycol monomethyl ether or propylene glycol diethyl ether; and, hydrocarbon-based solvents such as toluene or xylene.

In the condensation reaction product solution, the solvent having a boiling point of 100° C. to 200° C. (for example, one or more types of solvents selected from the group consisting of alcohol-, ketone-, ester-, ether- and hydrocarbon-based solvents) preferably composes 50% by weight or more of all solvents contained in the condensation reaction product solution. In this case, a solvent having a boiling point of below 100° C. may also be mixed into the condensation reaction product solution. In the case a solvent having a boiling point of 100° C. to 200° C. (for example, one or more types of solvents selected from the group consisting of alcohol-, ketone-, ester-, ether- and hydrocarbon-based solvents) composes 50% by weight or more of all solvents, the pot life of the condensation reaction product solution is prolonged and film formation of the coating composition is favorable, thereby making this preferable.

(Production of Condensation Reaction Product Solution)

The following provides an explanation of a preferable method for producing a condensation reaction product solution able to be used for the coating composition. The condensation reaction product solution can be produced by a method comprising:

a first step for obtaining a polysiloxane compound by carrying out hydrolytic polycondensation on two or more types of silane compounds represented by the following general formula (1):

R¹ₙSiX¹₄₋ₙ (1)

(wherein, n represents an integer of 0 to 3, R¹ represents a hydrogen atom or hydrocarbon group having 1 to 10 carbon atoms, and X¹ represents a halogen atom, alkoxy group having 1 to 6 carbon atoms or an acetoxy group) that at least contain a tetrafunctional silane compound in which n in general formula (1) is 0 and a trifunctional silane compound in which n in general formula (1) is 1, and

a second step for carrying out a condensation reaction on a condensation component at least containing 40% by weight to 99% weight of the polysiloxane compound obtained in the first step as the condensed weight thereof, and 1% by weight to 60% by weight of silica particles.

A solvent can be added to the reaction system or allowed to be present therein at a suitable time in either the aforementioned first step or second step or in both steps. In addition, an arbitrary third step for further adding solvent can be contained after the second step. In the third step, solvent replacement treatment may be carried out after adding solvent to remove water and solvent having a boiling point of 100° C. or lower, for example.

In a more preferable aspect, in the aforementioned first step, a silane compound consisting of a combination of 5 mol % to 40 mol % of a tetrafunctional silane compound represented by the following general formula (2):

SiX²₄ (2)

(wherein, X² represents a halogen atom, alkoxy group having 1 to 6 carbon atoms or an acetoxy group) and 60 mol % to 95 mol % of a trifunctional silane compound represented by the following general formula (3):

R²SiX³₃ (3)

(wherein, R² represents a hydrocarbon group having 1 to 10 carbon atoms and X³ represents a halogen atom, alkoxy group having 1 to 6 carbon atoms, or an acetoxy group) can be used for the silane compound represented by general formula (1).

The first step can be carried out using a technique described in detail in the section describing production of the polysiloxane compound.

In the aforementioned second step, when the aforementioned silica particles are subjected to a condensation reaction with the aforementioned polysiloxane compound, the reaction can be allowed to proceed using silica particles dispersed in a solvent. This solvent can be water, an organic solvent or a mixed solvent thereof. The type of organic solvent present in the reaction system during the aforementioned condensation reaction varies according to the dispersion medium in which the silica particles used are dispersed. In the case the dispersion medium of the silica particles used is an aqueous medium, an aqueous dispersion medium obtained by adding water and/or alcohol-based solvent to the silica particles may be reacted with the polysiloxane compound, or water contained in an aqueous dispersion of the silica particles may first be replaced with an alcohol-based solvent, followed by reacting this alcohol-based dispersion of silica particles with the polysiloxane compound. The alcohol-based solvent used is preferably an alcohol-based solvent having 1 to 4 carbon atoms, examples of which include methanol, ethanol, n-propanol, 2-propanol, n-butanol, methoxyethanol and ethoxyethanol. These solvents are preferable since they are readily miscible with water.

In the case the dispersion medium of the silica particles used is an alcohol-, ketone-, ester- or hydrocarbon-based solvent, water or alcohol-, ether-, ketone- or ester-based solvent can be used as solvent present in the reaction system during the condensation reaction. Examples of alcohols include methanol, ethanol, n-propanol, 2-propanol and n-butanol. Examples of ethers include dimethoxyethane. Examples of ketones include acetone, methyl ethyl ketone and methyl isobutyl ketone. Examples of esters include methyl acetate, ethyl acetate, propyl acetate, ethyl formate and propyl formate.

In a preferable aspect, the second step can be carried out in an aqueous solution of an alcohol having 1 to 4 carbon atoms.

The pH of the reaction system when subjecting the polysiloxane compound and silica particles to the condensation reaction is preferably within the range of 4 to 9, more preferably within the range of 5 to 8, and particularly preferably within the range of 6 to 8. In the case the pH is within the aforementioned ranges, the weight average molecular weight of the condensation reaction product and the ratio of silanol groups of component Q can be easily controlled, thereby making this preferable.

The condensation reaction between the polysiloxane compound and the silica particles is normally carried out in the presence of an acid catalyst. Examples of acid catalysts include the same acid catalysts as those previously described as being used to produce the polysiloxane compound. Although it is normally necessary to repeat addition of acid catalyst when reacting the polysiloxane compound and the silica particles in the case of having removed the acid catalyst following production of the polysiloxane compound, in the case of reacting the silica particles without removing the acid catalyst following production of the polysiloxane compound, the reaction between the polysiloxane compound and the silica particles can be carried out with the acid catalyst used when reacting the polysiloxane compound without having to add the acid catalyst again. In this case, however, acid catalyst may also be added again during the reaction between the polysiloxane compound and the silica particles.

The temperature of the reaction between the polysiloxane compound and the silica particles is preferably 0° C. to 200° C. and more preferably 50° C. to 150° C. In the case the reaction temperature is within the aforementioned ranges, the weight average molecular weight of the condensation reaction product and the ratio of silanol groups of component Q can be easily controlled, thereby making this preferable.

In a particularly preferable aspect, the condensation reaction between the polysiloxane compound and the silica particles is carried out at a temperature of 50° C. or higher under conditions of pH 6 to 8 in an aqueous solution of an alcohol containing 1 to 4 carbon atoms.

In the case of using a silane compound represented by the aforementioned general formula (1) as a condensation component, after the condensation reaction between the polysiloxane compound and the silica particles (first stage), a silane compound can be further reacted with the product of the condensation reaction in the second step (second stage). The silane compound may be added as is or may be added after first diluting with a solvent. Examples of diluting solvents that can be used include alcohol-, ether-, ketone-, ester- and hydrocarbon-based solvents as well as halogenated solvents.

In the aforementioned second step, a silane compound represented by the aforementioned general formula (1) is preferably added to the reaction system within the range of a concentration of 1% by weight to 100% by weight (100% by weight in the case of not diluting), and the concentration is more preferably 3% by weight to 50% by weight. In the case the aforementioned concentration is within the aforementioned ranges, only a small amount of solvent is used when producing the condensation reaction product, thereby making this preferable.

In a typical aspect, a reaction product of the polysiloxane compound and the silica particles is preferably formed in the first stage, and in the subsequent second stage, a silane compound represented by general formula (1) is preferably added to the reaction system and allowed to react at a temperature within the range of −50° C. to 200° C. for a duration within the range of 1 minute to 100 hours. By controlling the reaction temperature and reaction time, the viscosity of the condensation reaction product solution when forming a film of the condensation reaction product can be controlled, and in the case the reaction temperature and reaction time are within the aforementioned ranges, the aforementioned viscosity can be controlled to a particularly preferable range for film formation.

The pH of the reaction solution following the condensation reaction (reaction between the polysiloxane compound and the silica particles or the reaction between the polysiloxane compound, silica particles and silane compound) is preferably adjusted to 6 to 8. The pH can be adjusted by, for example, removing acid by distillation following the condensation reaction. In the case the aforementioned pH is within the aforementioned range, the pot life of the condensation reaction product solution can be prolonged, thereby making this preferable.

A solvent selected from the group consisting of alcohol-, ketone-, ester-, ether- and hydrocarbon-based solvents (and preferably that having a boiling point of 100° C. to 200° C.) may be added in advance at the time of the condensation reaction (reaction between the polysiloxane compound and silica particles or reaction between the polysiloxane compound, silica particles and silane compound), may be added by providing a third step after carrying out the aforementioned condensation reaction, or may be added at both times.

In the case of providing a third step after having formed the condensation reaction product, a solvent having a boiling point of 100° C. to 200° C. selected from the group consisting of alcohol-, ketone-, ester-, ether- and hydrocarbon-based solvents may be further added to a concentrate obtained by removing the solvent used during the condensation reaction by a method such as distillation.

In the case the solvent (and particularly an organic solvent) used during the condensation reaction of the second step (reaction between the polysiloxane compound and silica particles or reaction between the polysiloxane compound, silica particles and silane compound) and the alcohol formed during the condensation reaction have a boiling point lower than the solvent having a boiling point of 100° C. to 200° C. selected from the group consisting of alcohol-, ketone-, ester-, ether- and hydrocarbon-based solvents, the solvent having a boiling point of 100° C. to 200° C. selected from the group consisting of alcohol-, ketone-, ester-, ether- and hydrocarbon-based solvents is preferably added during or after the condensation reaction, and the solvent having the lower boiling point is preferably subsequently removed by a method such as distillation. In this case, the pot life of the condensation reaction product solution is prolonged, thereby making this preferable.

In a particularly preferable aspect, after having added at least one type solvent having a boiling point of 100° C. to 200° C. selected from the group consisting of alcohol-, ketone-, ester-, ether- and hydrocarbon-based solvents to the reaction solution in the third step following the condensation reaction, components having a boiling point of 100° C. or lower are distilled off. As a result, the solvent can be replaced with a high boiling point solvent. Examples of components having a boiling point of 100° C. or lower include water and alcohols having a boiling point of 100° C. or lower in the case of having carried out the first step and/or second step in an aqueous alcohol solution or in an alcohol having a boiling point of 100° C. or lower.

More specifically, in the case of using water or an alcohol during the condensation reaction (reaction between the polysiloxane compound and silica particles or reaction between the polysiloxane compound, silica particles and silane compound), after having added solvent in an aspect as previously described following the condensation reaction, water and alcohols having a boiling point of 100° C. or lower are preferably removed by a method such as distillation, and the content of components having a boiling point of 100° C. or lower in the condensation reaction product solution (namely, water and alcohols having a boiling point of 100° C. or lower) is preferably made to be 1% by weight or less. In the case the content thereof is within the aforementioned range, the pot life of the condensation reaction product solution is prolonged, thereby making this preferable.

After having obtained the condensation reaction product solution according to a procedure like that described above, purification may be carried out to remove ions. Examples of methods used to remove ions include ion exchange using an ion exchange resin, ultrafiltration and distillation.

A more preferable method for producing a condensation reaction product solution able to be used for the coating composition in the present invention is a method comprising:

a first step for obtaining a polysiloxane compound by carrying out hydrolytic polycondensation in an aqueous alcohol solution under weakly acidic conditions of pH 5 to less than 7 on a silane compound consisting of 5 mol % to 40 mol % of a tetrafunctional silane compound represented by the following general formula (2):

SiX²₄ (2)

(wherein, X² represents a halogen atom, alkoxy group having 1 to 6 carbon atoms or an acetoxy group) and 60 mol % to 95 mol % of a trifunctional silane compound represented by the following general formula (3):

R²SiX³₃ (3)

(wherein, R² represents a hydrocarbon group having 1 to 10 carbon atoms and X³ represents a halogen atom, alkoxy group having 1 to 6 carbon atoms, or an acetoxy group),

a second step for obtaining a reaction solution by carrying out a condensation reaction on a condensation component composed of 40% by weight to 99% weight of the polysiloxane compound obtained in the first step as the condensed weight thereof, and 1% by weight to 60% by weight of silica particles in an aqueous solution of an alcohol having 1 to 4 carbon atoms and under conditions of pH 6 to 8 and temperature of 50° C. or higher, and

a third step for obtaining a condensation reaction product solution by adding at least one type of solvent having a boiling point of 100° C. to 200° C. selected from the group consisting of alcohol-, ketone-, ester-, ether- and hydrocarbon-based solvents to the reaction solution obtained in the second step, followed by distilling off components having a boiling point of 100° C. or lower by distillation.

### EXAMPLES

The following provides a more detailed explanation of the present invention using examples thereof.

<Structure of Test Substrate>

The structure of a test substrate used in the examples is shown in FIG. 2. This test substrate 2 has test pattern structures 22 in the form of a narrow width region 23 and a wide width region 24 formed in an Si wafer 21 having a diameter of 6 inches. Trenches 26 having a width of 30 nm in the narrow width region 23 and trenches 27 having a width of 300 nm in the wide width region 24 are both formed within the same layer. Furthermore, the trenches 26 having a width of 30 nm and the trenches 27 having a width of 300 nm are arranged mutually in parallel, and the depth is 1 μm in all cases.

<Detection of Nanostructure>

After cutting the test substrate in a direction at a right angle to the lengthwise direction of the trenches, thin sections having a thickness of about 30 nm were prepared using a focused ion beam (FIB) method, and the thin sections were examined for nanostructure using a transmission electron microscope (TEM).

<Evaluation of Trench-Fill Capability>

The test substrate was cut in a direction at a right angle to the lengthwise direction of the trenches and the cross-section thereof was observed with an SEM (SEM) to observe and evaluate the presence or absence of voids having a size of 3 nm or more.

<Evaluation of Hydrofluoric Acid Resistance for Filled Trench>

Prior to observing a cross-section prepared in the manner described above, the test substrate was immersed in hydrofluoric acid having a concentration of 0.5% by weight for 5 minutes at 23° C. followed by rinsing with pure water and drying. This cross-section was then observed with an SEM in the same manner as previously described and then evaluated for the presence or absence of voids having a size of 3 nm or more, and the absence of voids was judged to indicate hydrofluoric acid resistance.

<Evaluation Crack Prevention Performance>

An exposed surface of the wide width region of the test substrate was observed with an SEM and evaluated based on the maximum film thickness at which cracks measuring 100 nm or more in length do not form. Namely, crack prevention performance was judged to be better the thicker this film thickness.

### Polysiloxane Compound Production Examples

### Production Example 1

11.6 g of methyl trimethoxysilane (MTMS), 4.4 g of tetraethoxysilane (TEOS) and 20 g of ethanol were placed in a recovery flask followed by adjusting the pH to 6 to 7 by dropping in at room temperature a mixed aqueous solution of 11.5 g of water and a suitable amount of concentrated nitric acid for adjusting pH. Following completion of dropping, the solution was stirred for 30 minutes and then allowed to stand undisturbed for 24 hours.

### Production Example 2

The same procedure as Production Example 1 was carried out with the exception of not using the MTMS of Production Example 1 and using 24.3 g of TEOS.

### Production Example 3

The same procedure as Production Example 1 was carried out with the exception of not using the TEOS of Production Example 1 and using 14.2 g of MTMS.

### Example 1

47.6 g of PL-06L (water-dispersed silica particles having an average primary particle diameter of 6 nm and concentration of 6.3% by weight manufactured by Fuso Chemical Co., Ltd.) and 80 g of ethanol were placed in a 500 mL 4-mouth flask equipped with a distillation column and dropping funnel followed by stirring for 5 minutes and dropping in the polysiloxane compound synthesized in Production Example 1. Following completion of dropping and stirring for 30 minutes, the solution was refluxed for 4 hours. After refluxing, 150 g of propylene glycol methyl ether acetate (PGMEA) were added followed by distilling off the methanol, ethanol, water and nitric acid through a distillation line by heating with an oil bath to obtain a PGMEA solution of a condensation reaction product. The PGMEA solution of this condensation reaction product was then concentrated to obtain a PGMEA solution having a solid fraction concentration of 20% by weight.

### Examples 2 to 5

Condensation reaction product solutions were prepared under the same conditions as Example 1 using the polysiloxane compounds synthesized in Production Examples 1 to 3 and the water-dispersed silica particles PL-06L in the incorporated amounts shown in Table 1.

TABLE 1

| | Example 1 | Example 2 | Example 3 | Example 4 | Example 5 |
|---|---|---|---|---|---|
| MTMS (g) | 20.7 | 11.6 | 11.6 | 14.2 | 0 |
| TEOS (g) | 3.5 | 4.4 | 4.4 | 0 | 24.3 |
| PL-06 (g) | 76.3 | 47.6 | 258.5 | 0 | 0 |

2 mL of each condensation reaction product solution was dropped onto the test substrate followed by carrying out spin coating in two stages consisting of 10 seconds at a rotating speed of 300 rpm and 30 seconds at a rotating speed of 300 rpm. A plurality of test substrates having different film thicknesses were fabricated by changing the second stage rotating speed. The test substrates were pre-baked in air for 2 minutes at 100° C. and 5 minutes at 140° C. on a hot plate to remove the solvent. The resulting test substrates were then heated to 600° C. at the rate of 5° C./min and then baked for 30 minutes at 600° C. in an atmosphere having an oxygen concentration of 10 ppm or less, followed by cooling to room temperature at the rate of 2° C./min.

Examples 1 to 5 were evaluated for detection of nanostructure, trench-fill capability, trench internal hydrofluoric acid resistance and crack prevention performance. The results are shown in Table 2.

TABLE 2

| | | | hydrofluoric acid | Crack |
|---|---|---|---|---|
| | Detection of | Trench-fill | resistance for | prevention |
| | nanostructure | capability | Filled Trench | performance |
| Example 1 | 10-20 nm | No voids | Resistant | >1.5 μm |
| Example 2 | 10-20 nm | No voids | Not resistant | >1.5 μm |
| Example 3 | 10-20 nm | No voids | Not resistant | 1.0 μm |
| Example 4 | Not observed | No voids | Resistant | 1.0 μm |
| Example 5 | Not observed | No voids | Not resistant | 1.0 μm |

### INDUSTRIAL APPLICABILITY

The present invention can be preferably used in the production of various semiconductor devices, such as non-volatile memory, NAND flash memory, resistive memory or magnetoresistive memory, and can be used particularly preferably in the production highly integrated semiconductor memory.

Although the foregoing description has indicated examples of aspects of the present invention, the present invention is not limited to these aspects, but rather should be understood to be able to be modified in various ways within the spirit and scope of the claims for patent.

### BRIEF DESCRIPTION OF THE REFERENCE SYMBOLS

1 Insulating structure
11 Substrate
12 Circuit pattern
13,23 Narrow width region
13a Narrow width pattern
14,24 Wide width region
14a Wide width pattern
15 Insulating composition
16 Circuit member
2 Test substrate
21 Si wafer
22 Pattern structure
26 30 nm wide trench
27 300 nm wide trench

1. An insulating structure comprising a substrate and a circuit pattern formed on the substrate, wherein
the circuit pattern has a narrow width region having a narrow width pattern of a width of 30 nm or less and a wide width region having a wide width pattern of a width of greater than 100 nm in the same layer, and
the same insulating composition is formed within the narrow width pattern and within the wide width pattern.

2. The insulating structure according to claim 1, wherein the film thickness of the insulating composition present within the wide with pattern is 1.5 μm to 4.0 μm.

3. The insulating structure according to claim 1,
wherein the film thickness of the insulating composition present within the wide width pattern is 0.8 μm to 1.5 μm.

4. The insulating structure according to any of claims 1 to 3, wherein the insulating composition present within the wide width pattern does not have cracks.

5. The insulating structure according to any of claims 1 to 4, wherein the insulating composition present within the narrow width pattern does not have voids.

6. The insulating structure according to any of claims 1 to 5, wherein the insulating composition present within the narrow width pattern has resistance to hydrofluoric acid.

7. The insulating structure according to any of claims 1 to 6, wherein the depth of the narrow width pattern is 0.4 μm or more.

8. The insulating structure according to claim 7, wherein the depth of the narrow width pattern is 0.5 μm to 3 μm.

9. The insulating structure according to claim 8, wherein the depth of the narrow width pattern is 1 μm to 2 μm.

10. The insulating structure according to any of claims 1 to 9, wherein the length of the narrow width pattern is 50 nm to 10 μm.

11. The insulating structure according to any of claims 1 to 10, wherein the narrow width pattern is a pattern of a width of 10 nm to 30 nm.

12. The insulating structure according to any of claims 1 to 11, wherein the wide width pattern is a pattern of a width of greater than 100 nm to 100 μm.

13. The insulating structure according to any of claims 1 to 12, wherein the substrate is composed of a semiconductor or insulator.

14. The insulating structure according to any of claims 1 to 13, wherein the insulating composition has a nanostructure of a particle diameter of 3 nm to 30 nm.

15. An insulating structure comprising a substrate and a circuit pattern formed on the substrate, wherein
the circuit pattern has a narrow width region having a pattern of a width of 30 nm or less and a wide width region having a pattern of a width of greater than 100 nm within the same layer,
the same insulating composition is formed within the pattern having a width of 30 nm or less in the narrow width region and within the pattern of a width of greater than 100 nm in the wide width region, and
the insulating composition has a nanostructure of a particle diameter of 3 nm to 30 nm.

16. The insulating structure according to claim 14 or 15, wherein the ratio of the portion having the nanostructure in the insulating composition is 1% by weight to 60% by weight.

17. The insulating structure according to any of claims 14 to 16, wherein the insulating composition contains 50% by weight to 100% by weight of a condensation reaction product of a polysiloxane compound and a silica particles having an average primary particle diameter of 3 nm to 30 nm, and
the ratio of a hydrolytic condensation structure of at least one type of tetraalkoxysilane and at least one type of alkyl trialkoxysilane in the entire condensation reaction product is 40% by weight to 99% by weight.

18. A production method of the insulating structure according to any of claims 1 to 17, comprising:
a step for preliminarily forming patterns corresponding to the narrow width region and the wide width region on a substrate,
a step for coating a coating composition for forming the insulating composition on the patterns, and
a step for converting the coated coating composition to the insulating composition by heating.

19. The insulating structure production method according to claim 18, wherein the coating composition is a condensation reaction product solution comprising:
(I) a condensation reaction product obtained by a condensation reaction of a condensation component containing at least (i) 40% by weight to 99% by weight as the condensed amount thereof of a polysiloxane compound derived from a silane compound represented by the following general formula (1):
R¹ₙSiX¹₄₋ₙ (1)
(wherein, n represents an integer of 0 to 3, R¹ represents a hydrocarbon group having 1 to 10 carbon atoms, and X¹ represents a halogen atom, an alkoxy group having 1 to 6 carbon atoms, or an acetoxy group), and (ii) 1% by weight to 60% by weight of silica particles, and
(II) a solvent, and
the silane compound represented by the general formula (1) consists of two or more types of silane compounds comprising at least a tetrafunctional silane compound in which n in general formula (1) is 0 and a trifunctional silane compound in which n in general formula (1) is 1.
